(19) United States
(12) Patent Application Publication
(10) Pub. No.: US 2005/0099775 A1
(43) Pub. Date: May 12, 2005

(54) Pumped liquid cooling for computer systems using liquid metal coolant

(76) Inventors: Himanshu Pokharna, San Jose, CA (US); Eric Distefano, Livermore, CA (US)

Correspondence Address: INTEL CORPORATION, P.O. BOX 5326, SANTA CLARA, CA, 95056-5326, US

(21) Appl. No.: 10/712,191

(22) Filed: Nov. 12, 2003

(51) Int. Cl. H05K 7/20

(52) U.S. Cl. 361/700

(57) ABSTRACT

Apparatus and method are provided to enable cooling electronic components in computer systems using liquid metal as a coolant. The liquid metal coolant extracts heat generated by an electronic component and flows to a heat exchanger where the heat is rejected into ambient air through force convection. A pump is used to enable the liquid metal coolant to circulate in a closed loop system.

### COPYRIGHT NOTICE

Contained herein is material that is subject to copyright protection. The copyright owner has no objection to the facsimile reproduction of the patent disclosure by any person as it appears in the Patent and Trademark Office patent files or records, but otherwise reserves all rights to the copyright whatsoever.

### FIELD OF THE INVENTION

The present invention generally relates to cooling systems. More specifically, the present invention relates to cooling computer systems using liquid metal coolant.

### BACKGROUND

As computer systems become faster, electronic components in the computer systems generate more heat requiring more efficient cooling techniques. One cooling technique is liquid cooling. Liquid cooling may be able to accommodate faster and denser electronic components because of their higher amount of power dissipation and heat generation. One category of liquid cooling is indirect liquid cooling. In indirect liquid cooling, the electronic component does not come in direct contact with the coolant. Heat generated by the electronic component may be transferred to the coolant. The heat may then be directed toward a heat exchanger for cooling. Typically, the coolant is stored in a heat pipe. One disadvantage to using the heat pipe is due to its limited capability to move the heat toward the heat exchanger. Techniques are being developed to improve the cooling effect of indirect liquid cooling.

### BRIEF DESCRIPTION OF THE DRAWINGS

Embodiments of the present invention are illustrated by way of example, and not by way of limitation, in the figures of the accompanying drawings and in which like reference numerals refer to similar elements and in which:

FIG. 1A is a block diagram illustrating an example of a liquid cooling system using liquid metal coolant, in accordance with one embodiment.

FIG. 1B is a block diagram illustrating an example of a technique used to evacuate air from the liquid cooling system and filling it with liquid metal coolant, in accordance with one embodiment.

FIG. 2A is a diagram illustrating one example of a single-pass heat exchanger that may be used to cool the liquid metal coolant, in accordance with one embodiment.

FIG. 2B is a diagram illustrating one example of a multi-pass heat exchanger that may be used to cool the liquid metal coolant, in accordance with one embodiment.

FIG. 3A is a diagram illustrating one example of a liquid cooling system using liquid metal coolant and cold plates in series, in accordance with one embodiment.

FIG. 3B is a diagram illustrating one example of a liquid cooling system using liquid metal coolant and cold plates in parallel, in accordance with one embodiment.

FIG. 4A is a diagram illustrating a side view of one example of a liquid cooling system using liquid metal coolant and a heat spreader, in accordance with one embodiment.

FIG. 4B is a diagram illustrating a top view of one example of a liquid cooling system using liquid metal coolant and a heat spreader, in accordance with one embodiment.

FIG. 5 is a diagram illustrating one example of a liquid cooling system 500 using liquid metal coolant and a heat pipe, in accordance with one embodiment.

FIG. 6 is a flow diagram illustrating one example of a process that cool electronic components in a computer system using liquid metal as a coolant, in accordance with one embodiment.

FIG. 7 is a flow diagram illustrating one example of a process that may be used to fill a loop with a liquid metal coolant, in accordance with one embodiment.

### DETAILED DESCRIPTION

For one embodiment, an apparatus and a method for cooling electronic components in a computer system using a liquid cooling system is disclosed. The liquid cooling system may include a pump, a heat exchanger, and a liquid metal coolant. The liquid cooling system may enable heat generated by an electronic component in the computer system to be transferred to the liquid metal coolant and cooled by the heat exchanger.

In the following description, for purposes of explanation, numerous specific details are set forth in order to provide a thorough understanding of the present invention. It will be evident, however, to one skilled in the art that the present invention may be practiced without these specific details. In other instances, well-known structures, processes and devices are shown in block diagram form or are referred to in a summary manner in order to provide an explanation without undue detail.

As used herein, the term “when” may be used to indicate the temporal nature of an event. For example, the phrase “event ‘A’ occurs when event ‘B’ occurs” is to be interpreted to mean that event A may occur before, during, or after the occurrence of event B, but is nonetheless associated with the occurrence of event B. For example, event A occurs when event B occurs if event A occurs in response to the occurrence of event B or in response to a signal indicating that event B has occurred, is occurring, or will occur.

Reference in the specification to “one embodiment” or “an embodiment” of the present invention means that a particular feature, structure or characteristic described in connection with the embodiment is included in at least one embodiment of the present invention. Thus, the appearances of the phrase “for one embodiment” or “in accordance with one embodiment” appearing in various places throughout the specification are not necessarily all referring to the same embodiment.

Liquid Metal Cooling System

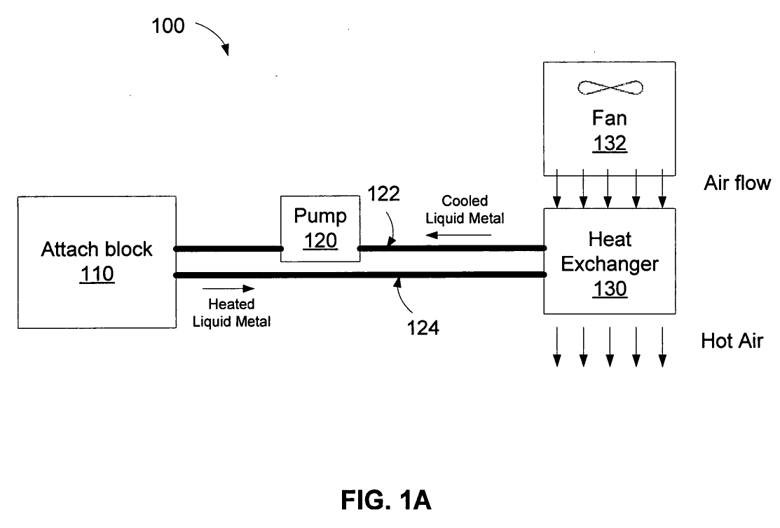

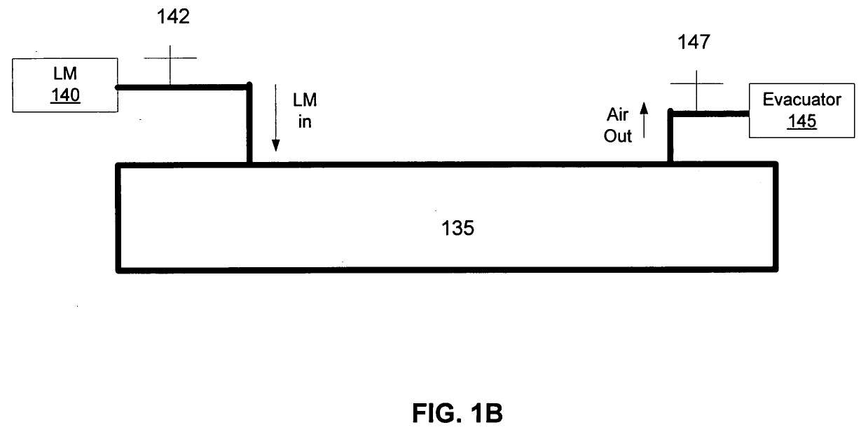

FIG. 1A is a block diagram illustrating an example of a liquid cooling system using liquid metal coolant, in accordance with one embodiment. For one embodiment, liquid cooling system 100 may include an attach block 110 which may be attached to an electronic component (not shown) capable of generating heat. For example, the electronic component may be a processor, a graphics controller, etc. In this example, the liquid cooling system 100 may include tubes 122, 124 coupled to the attach block 110.

The tubes 122, 124 may be implemented using a rigid and flexible material. The rigidity and flexibility properties of the tube material may enable the tubes 122, 124 to be easily routed around other electronic components inside the computer system. This may also enable the liquid cooling system 100 to be implemented with remote heat exchanger (RHE) 130 placed at a distance from the attach block 110. For one embodiment, the tube material may be thermally conductive. For example, the tubes 122, 124 may be metal tubes, although other types of materials that allow heated liquid coolant to flow through may also be used, depending on the type of coolant or application. It may be noted that the tubes 122, 124 may not be heat pipes as typically used in cooling systems.

The RHE 130 may be coupled to a fan 132 which creates air flow. The RHE 130 may include fins (not shown). The fan 132 may be mounted directly to the RHE 130 or may be positioned next to the RHE 130. To enhance the flow of the coolant between the attach block 110 and the RHE 130, pump 120 may be used. The pump 120 may be a mechanical pump or an electromagnetic pump. For example, the pump 120 may be a conduction pump, induction pump, centrifugal pump, regenerative turbo pump, magneto-hydrodynamics (MHD) pump, prezo-electrical pump, etc

The pump 120 may be used with the tube 122 or both the tubes 122 and 124. In the example illustrated in FIG. 1A, the tube 122 is one that transports cooled liquid coolant from the direction of the RHE 130, and the tube 124 is one that transports hot liquid coolant from the direction of an electronic component.

For one embodiment, the coolant may be liquid metal, and the tube material may be of a type that allows heated liquid metal coolant to flow through. Liquid metal coolant typically has high thermal conductivity property, and thus may enable it to easily extract the heat generated by the electronic component that is attached to the attach block 110. The liquid metal coolant may be of a type that has low freezing point (liquid to solid) and high boiling point (liquid to gas) properties. For one embodiment, the freezing point may be −10 degrees Celsius or below. The boiling point may be very high (e.g., 2080 degrees Celsius or higher). This may enable the liquid cooling system 100 to operate in various temperature conditions. For one embodiment, the liquid metal coolant may be Indium (In), Gallium (Ga), or a mixture of Indium and Gallium with trace amounts of other metals such as, for example, zinc, copper, etc. Liquid metal is known to one skilled in the art.

For one embodiment, the liquid cooling system 100 may be a closed-loop system. In the closed-loop system, the liquid metal coolant circulates between the attach block 110 and the RHE 130 or between one area of the computer system and another area of the computer system. Referring to the example illustrated in FIG. 1A, the tube 122 and the tube 124 may be part of the same loop that connects the attach block 110 and the RHE 130. The liquid metal coolant extracts heat from the electronic component at the attach block 110 and transfers the heat from the attach block 110 to the RHE 130 along the tube 124. The heat may then be rejected from the liquid metal coolant at the RHE 130 into ambient air. Cooled liquid metal coolant may then flow from the RHE 130 back to the attach block 110 along the tube 122. Although the current example describes the cooled liquid metal coolant flowing from the RHE 130 to the attach block 110 along the tube 122 and the heated liquid metal coolant flowing from the attach block 110 to the RHE 130 along the tube 124, one skilled in the art will recognize that the direction of flow may be reversed.

One disadvantage of using the liquid metal coolant is the possibility of oxidation of the liquid metal. For example, Ga—In reacts very easily with atmospheric oxygen and may form a layer in the tubes 122, 124 over time. This layer may break causing small particles to float along the inside of the tubes 122, 124. The particles may deposit themselves in the area near the pump 120, anywhere along the tubes 122, 124, or anywhere in the channels (not shown) in the attach block 110 and eventually may decrease the overall effectiveness of the liquid cooling system 100.

FIG. 1B is a block diagram illustrating an example of a coolant filling system used to evacuate air from the tube and to fill it with liquid metal coolant, in accordance with one embodiment. Loop 135 may be a closed loop when valves 142 and 147 are closed. The valve 147 may be referred to as an air valve 145 because it is associated with an air evacuator 145. The valve 142 may be referred to as a coolant valve 142 because it is associated with a liquid coolant tank or container 140. In order to remove to prevent oxidation, the air evacuator 145 may be used to extract or draw air out of the loop 135. The air evacuator 145 may include a vacuum pump (not shown). For example, drawing the air out of the loop 135 may be performed by closing the coolant valve 142 and opening the air valve 147. The air evacuator 145 may also include an indicator (not shown) to indicate when the process of drawing air out of the loop 135 is considered to be sufficiently completed. For example, the process may be considered to be sufficiently completed when the indicator indicates the pressure inside the loop 135 is less than 1 Torr. At that time, the air valve 147 may be closed. Of course, when the air evacuator is drawing air out of the loop 135, there may not be any opening to allow air to go back into the loop 135.

After the process of drawing air out of the loop 135 is completed and the air valve 147 is closed, the liquid coolant (e.g., liquid metal coolant) may then be introduced into the loop 135 from the hermetically sealed liquid coolant tank or container 140. The container 140 may store the liquid coolant at the atmospheric pressure. Once the coolant valve 142 is opened, the liquid coolant from the coolant container 140 may be automatically drawn into the loop because the air was previously drawn out of the loop 135. When the loop 135 is completely filled with the liquid coolant, the coolant valve 142 may be closed. The loop 135 may then be sealed and the coolant valve 142 and the air valve 147 may be removed. It may be noted that the air is drawn out of the loop 135 at a point that is different from a point where the liquid coolant is introduced into the loop 135. Although the example illustrated in FIG. 1B indicates two different valves, other techniques may also be used to evacuate the air from the loop and to introduce the liquid coolant, as long as the techniques follow the sequence described above.

Single-Pass Heat Exchanger

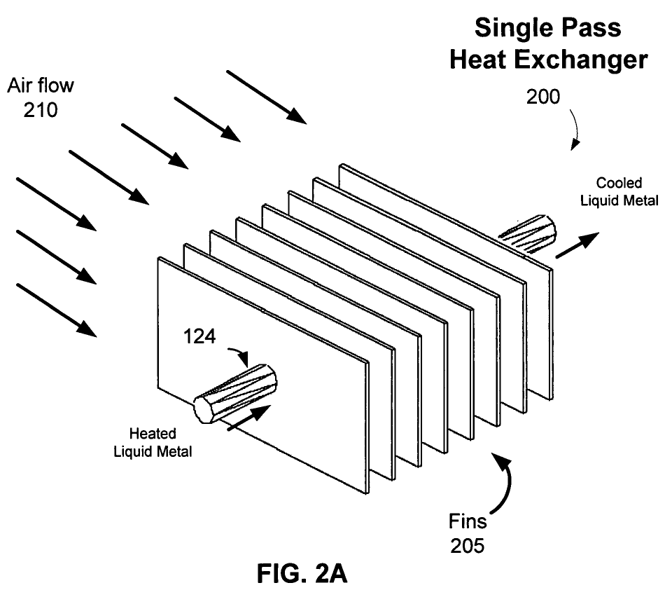

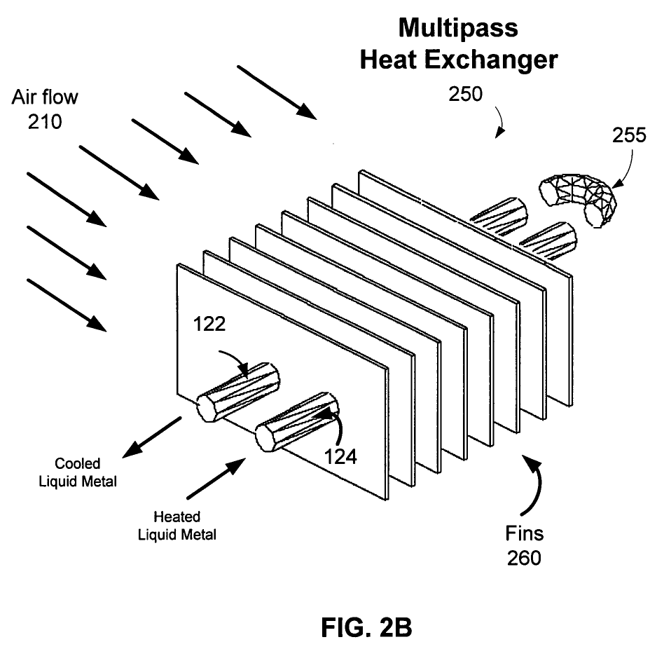

FIG. 2A is a diagram illustrating one example of a single-pass heat exchanger that may be used to cool the liquid metal coolant, in accordance with one embodiment. Single-pass heat exchanger 200 is referred to as a single pass because it accommodates one section of the loop (e.g., tube 124). It may be noted that only one section of the loop is illustrated in FIG. 2A, and that the loop may transport heated liquid coolant from the direction of a heat generating electronic component (not shown). The single-pass heat exchanger 200 may be an RHE and may include multiple fins 205. The multiple fins 205 may be manufactured using thermally conductive material and may be coupled with one section of the loop. Air flow 210 may be applied to the fins 205 and may be provided by a fan (e.g., fan 132). When heated liquid metal coolant flows through the section of the loop that couples to the fins 205, heat may be extracted from the heated liquid metal coolant by the fins 205. The heat may then be rejected from the fins 205 into the ambient air through force convection. The force convection is in the form of airflow 210 created by a fan (not shown).

Multi-Pass Heat Exchanger

FIG. 2B is a diagram illustrating one example of a multi-pass heat exchanger that may be used to cool the liquid metal coolant, in accordance with one embodiment. Multi-pass heat exchanger 250 may include similar elements (e.g., fins 205) as the single pass heat exchanger 200. However, the multi-pass heat exchanger 250 may accommodate more than one sections of the loop. As illustrated in the example in FIG. 2B, the multi-pass heat exchanger 250 may accommodate two sections. In this example, the heated liquid metal coolant may flow through the tube 124 to the first section of the loop that couples to the fins 260. The heat may be extracted from the heated liquid metal coolant by the fins 260 and rejected from the fins 260 into the ambient air by the air flow 210. This may be viewed as a first pass. Further heat from the liquid metal coolant may be extracted by the fins 260 during a second pass when the liquid metal coolant flows passed loop end 255 and returns to the second section of the loop that couples to the fins 260. Eventually, cooled liquid metal coolant may flow through the tube 122 to a heat generating electronic component (not shown). The flow of the liquid metal coolant through the tubes 122, 124 may be enhanced by the pump 120. Although the example illustrates two passes, one skilled in the art will recognize that implementations with more than two passes may also be possible.

Cold Plates in Series

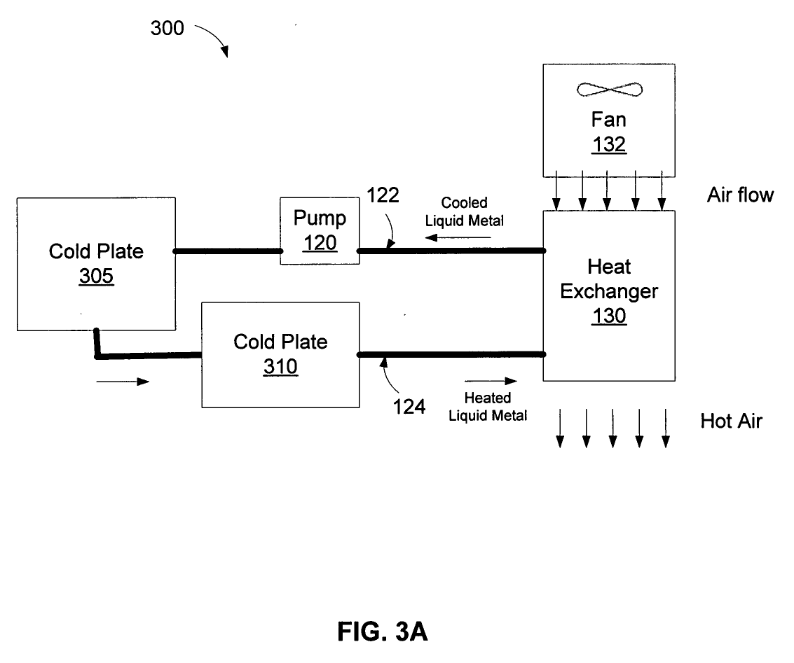

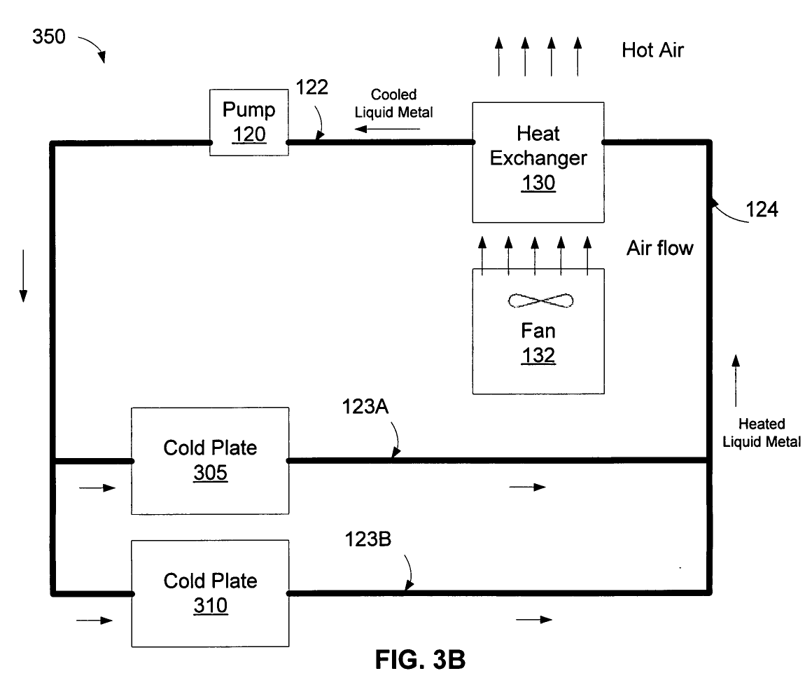

FIG. 3A is a diagram illustrating one example of a liquid cooling system using liquid metal coolant and cold plates in series, in accordance with one embodiment. For one embodiment, the attach block 110 in FIG. 1 may be a cold plate used to improve heat extracted from the electronic component. Liquid cooling system 300 may include cold plate 305 coupled with a first electronic component (not shown) and cold plate 310 coupled with a second electronic component (not shown). For example, the first electronic component may be a processor, and the second electronic component may be a graphics controller.

A thin film of thermally conductive material may be interposed between each of the cold plates 305, 310 and its associated electronic component. The film material may provide electrical insulation between the cold plate and its associated electronic component while introduces little thermal resistance. The cold plates 305, 310 may be used to improve the cooling of the first and second electronic components. In the current example, heat generated by the first electronic component may be transferred to the cold plate 305. The heat may then be transferred from the cold plate 305 to the liquid metal coolant. When the heated liquid metal coolant flows toward the second electronic component, heat generated by the second electronic component may be transferred to the cold plate 310, and the heat may then be transferred from the cold plate 310 to the liquid metal coolant. The heated liquid metal coolant may then flow toward the RHE 130 and cooled by the air flow created by the fan 132.

Cold Plates in Parallel

FIG. 3B is a diagram illustrating one example of a liquid cooling system using liquid metal coolant and cold plates in parallel, in accordance with one embodiment. Liquid cooling system 350 is somewhat similar to the liquid cooling system 300 illustrated FIG. 3A and may include the cold plate 305 coupled to a first electronic component (not shown) and cold plate 310 coupled to a second electronic component (not shown). For one embodiment, the cold plates 305, 310 may be positioned in parallel such that cooled liquid metal coolant may flow toward the cold plates 305, 310. After heat is transferred to the cold plates 305, 310 and to the liquid metal coolant, the heated liquid metal coolant may flow through tubes 123A, 123B respectively toward the tube 124 and eventually to the RHE 130 to be cooled by the air flow created by the fan 132.

Heat Spreader

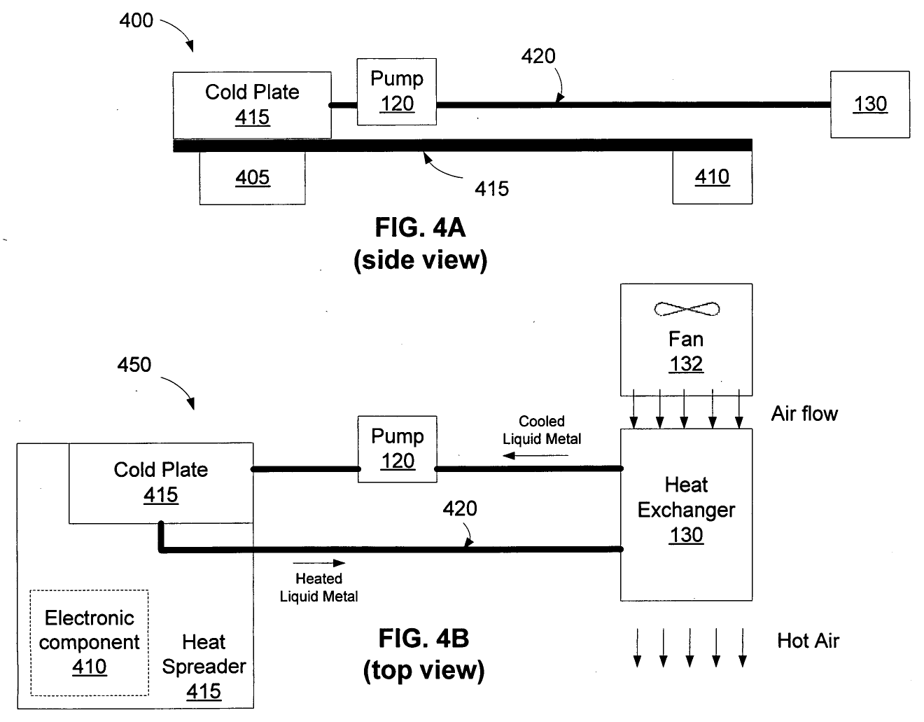

FIG. 4A is a diagram illustrating a side view of one example of a liquid cooling system 400 using liquid metal coolant and a spreader, in accordance with one embodiment. Liquid cooling system 400 may include a pump 120, an RHE 130 and a cold plate 415 connected to one another by tube 420. The cold plate 415 may be coupled to a first electronic component 405 (e.g., a processor) capable of generating heat. The tube 420 may be a loop tube (e.g., a closed-loop system) that transports liquid metal coolant between the RHE 130 and the cold plate 415 with the assistance of the pump 120. For one embodiment, the liquid cooling system 400 may also include a heat spreader 415. The heat spreader 415 may be manufactured using a material that conducts heat (e.g., copper). The heat spreader 415 may be coupled to a second electronic component 410 (e.g., a graphics controller) capable of generating heat. For example, the heat spreader 415 may cover the second electronic component 410 and may help distribute heat generated by the second electronic component 410 to a wider area. This may reduce the amount of heat concentrated around the second electronic component 410.

FIG. 4B is a diagram illustrating a top view of one example of a liquid cooling system 450 using liquid metal coolant and the heat spreader 415, in accordance with one embodiment. For one embodiment, the heat spreader 415 may be placed in between the cold plate 415 and the first electronic component 405. This may allow heat from the heat spreader 415 to be transferred to the cold plate 415 and to the liquid metal coolant flowing through the loop tube 420. The heated liquid metal coolant may then be cooled at the RHE 130 through force convection in the form of air flow created by the fan 132. Thus, in this embodiment, the RHE 130 may be used to help cooling the liquid metal coolant that extracts heat from the second electronic component 410 via the heat spreader 415.

Heat Pipe

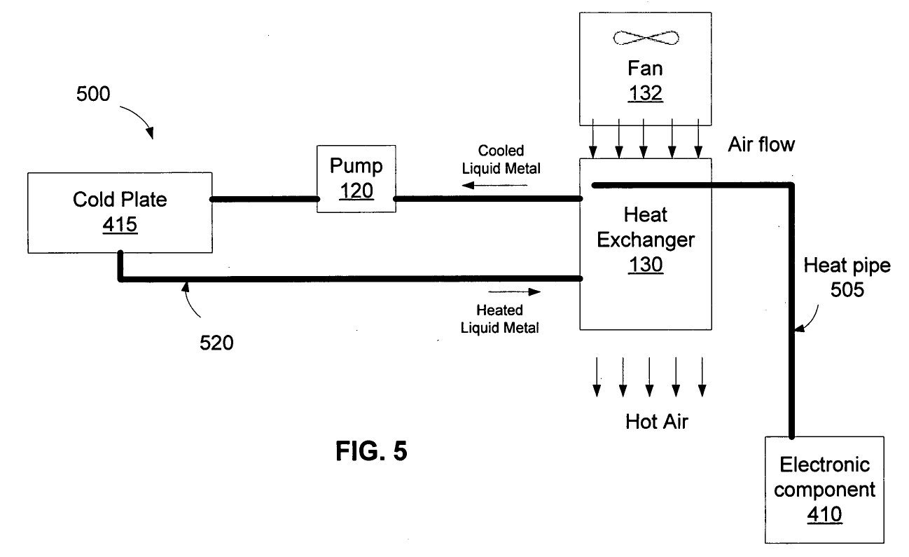

FIG. 5 is a diagram illustrating one example of a liquid cooling system 500 using liquid metal coolant and a heat pipe, in accordance with one embodiment. Liquid cooling system 500 may include a pump 120, an RHE 130, a cold plate 415 coupled to a first electronic component (not shown), a loop tube 520 that connects these elements to one another. For one embodiment, the liquid cooling system 500 may also include a heat pipe 505 coupled to a second electronic component 410 (e.g., a graphics controller) and may serve as a heat conductor to help distribute heat generated by the second electronic component 410. The heat pipe 505 may be coupled with the second electronic component 410 via an attach block or a heat spreader (not shown). For example, the heat spreader may be placed between the second electronic component 410 and the heat pipe 505 to enable the heat pipe 505 to extract as much heat from the second electronic component 410 as possible.

The heat pipe 505 may be a closed, evacuated cylindrical aluminum or copper vessel with internal walls lined with a capillary structure or wick that is saturated with a working fluid. The working fluid enters the pores of the wicking material, wetting all internal surfaces. Since the heat pipe 505 is evacuated and then charged with the working fluid prior to being sealed, the internal pressure is set by the vapor pressure of the fluid. As heat enters the heat pipe 505 at the second electronic component 410, the heat may cause the working fluid to vaporize. The vaporized fluid creates a pressure gradient, which forces the vapor to flow along the heat pipe 505 toward a condensation end of the heat pipe 505 and toward the RHE 130 where the vapor condenses giving up its latent heat of vaporization. The working fluid is then returned toward the second electronic component 410 in the heat pipe 505 by capillary forces developed in the wick structure. The wicking material serves as a pump to return the cooled working fluid toward the second electronic component 410. Thus, in this embodiment, the RHE 130 may be used to help cooling the liquid metal coolant flowing through the tube 520 and to condense vapor flowing through the heat pipe 505.

Process

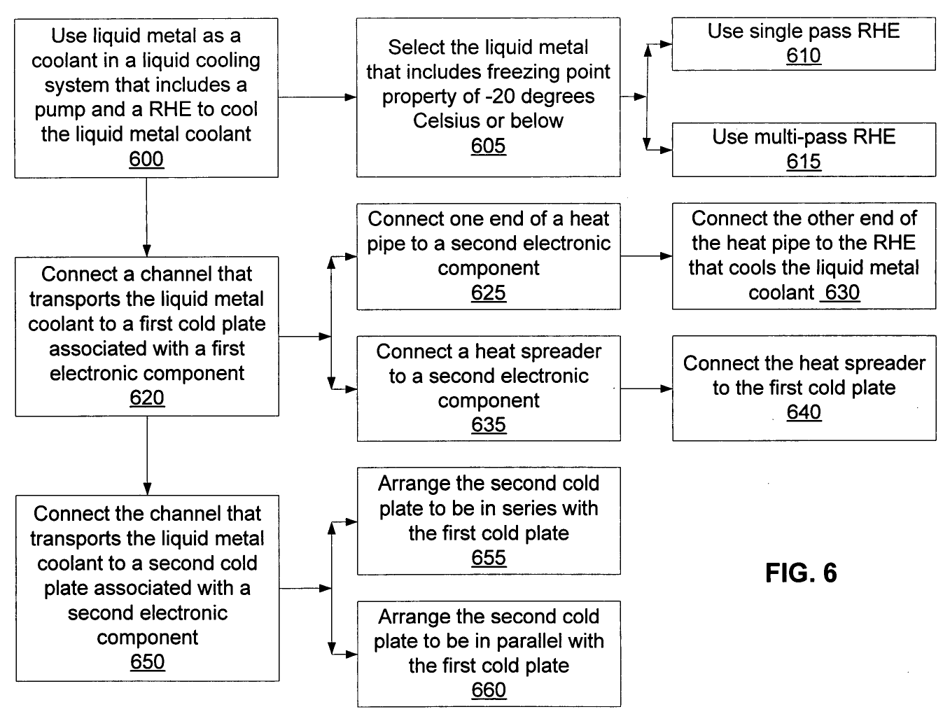

FIG. 6 is a flow diagram illustrating one example of a process that cool electronic components in a computer system using liquid metal as a coolant, in accordance with one embodiment. The process also has different possible routes with each route describing one embodiment. At block 600, liquid metal is introduced as a coolant in the liquid cooling system that includes a pump and an RHE to cool the liquid metal coolant. At block 605, the liquid metal selected is one that has a freezing property of −20 degrees Celsius or below. At block 610, the RHE selected to be used with the liquid cooling system is a single pass RHE. Alternatively, at block 615, the RHE selected to be used with the liquid cooling system is a multi-pass RHE.

From block 600, according with another embodiment, a loop tube that is used to transport the liquid metal coolant is coupled to a first cold plate, as shown in block 620. The first cold plate is associated with a first electronic component. At block 625, one end of a heat pipe is connected to a second electronic component. At block 630, another end of the heat pipe is connected to the RHE that is used to cool the liquid metal coolant. This may allow the RHE to cool the liquid metal coolant and to condense vapor in the heat pipe.

From block 620, according to another embodiment, a heat spreader may be connected to a second electronic component, as shown in block 635. At block 640, the heat spreader may be connected to the first cold plate. This may allow the liquid metal coolant to extract heat from the first cold plate and from the heat spreader.

From block 620, according to another embodiment, the tube that transports the liquid metal coolant may be connected to a second cold plate, as shown in block 650. The second cold plate may be associated with a second electronic component. At block 655, the second cold plate may be placed in series with the first cold plate. Alternatively, the second cold plate may be placed in parallel with the first cold plate, as shown in block 660.

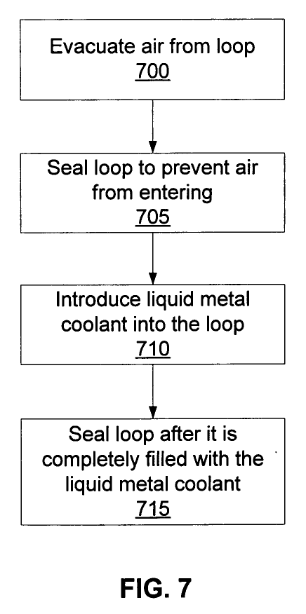

FIG. 7 is a flow diagram illustrating one example of a process that may be used to fill a loop with a liquid metal coolant, in accordance with one embodiment. The process may reduce the potential of oxidation and may help protect the efficiency of the cooling systems using the liquid metal coolant as described in the examples above. At block 700, air is evacuated from a loop used in the cooling system. This loop may include one or more sections of tubes used to carry the liquid metal coolant. As noted above, the one or more sections of tubes may not be heat pipes. That is, the internal surface structure of the tubes may not be the same as the internal surface structure of a heat pipe. At block 705, once the air has been evacuated from the loop, the loop may be closed to prevent air from entering. This may be done by closing an air valve. At this point, the air pressure inside the loop may be very low. At block 710, the liquid metal coolant is introduced into the loop. The liquid metal coolant may be introduced from a tank or container storing the liquid metal coolant at atmospheric pressure. The liquid metal coolant may be introduced through an opening in the loop without introducing air into the loop. When the loop is completely filled with the liquid metal coolant, this opening is sealed, as shown in block 715. This process may help prevent oxidation to occur, and as a result may help the cooling system that uses the loop maintain its efficiency.

For one embodiment, a combination of two or more of the techniques described above may be used to cool multiple electronic components in a computer system. For example, a liquid cooling system using liquid metal coolant may be used to cool electronic components in series and in parallel, with a heat pipe and/or with a heat spreader, and with a single-pass or with a multi-pass heat exchanger.

While the invention has been described in terms of several embodiments, those skilled in the art will recognize that the invention is not limited to the embodiments described, but can be practiced with modification and alteration within the spirit and scope of the appended claims. The description is thus to be regarded as illustrative instead of limiting.

1. A method comprising:
using a liquid metal coolant in a liquid cooling system to cool a first electronic component in a computer system, wherein the liquid metal includes a freezing point property of at least −10 degrees Celsius.

2. The method of claim 1, wherein the liquid metal coolant includes a mixture of Indium and Gallium.

3. The method of claim 2, wherein the liquid metal coolant further includes other metallic elements.

4. The method of claim 3, wherein the other metallic elements includes one or more of zinc and copper.

5. The method of claim 1, further comprising:
using a pump to transport the liquid metal coolant in a tube toward or away from a heat exchanger.

6. The method of claim 5, wherein the heat exchanger is a remote heat exchanger (RHE).

7. The method of claim 5, wherein the RHE is a single-pass RHE.

8. The method of claim 5, wherein the RHE is a multi-pass RHE.

9. The method of claim 6, further comprising:
using a heat pipe to extract heat from a second electronic component in the computer system, wherein a condensation end of the heat pipe is cooled by the RHE.

10. The method of claim 1, wherein the first electronic component associated with a first cold plate

11. The method claim 10, further comprising:
using a heat spreader to extract heat from a third electronic component in the computer system, wherein the heat spreader is coupled to the first cold plate.

12. The method of claim 5, wherein the pump is an electromagnetic pump.

13. The method of claim 5, wherein the pump is a mechanical pump.

14. The method of claim 1, further comprising:
using the liquid metal coolant to cool a fourth electronic component in the computer system, the fourth electronic component placed in series with the first electronic component.

15. The method of claim 1, further comprising:
using the liquid metal coolant to cool a fifth electronic component in the computer system, the fifth electronic component placed in parallel with the first electronic component.

16. An apparatus, comprising:
a heat exchanger; and
a pump coupled to the heat exchanger and is to enable a liquid metal coolant to flow in a tube toward the heat exchanger, wherein the liquid metal coolant is used to cool a first component in a computer system.

17. The apparatus of claim 16, wherein the pump is an electromagnetic pump.

18. The apparatus of claim 16, wherein the heat exchanger is a single-pass heat exchanger.

19. The apparatus of claim 16, wherein the heat exchanger is a multi-pass heat exchanger.

20. The apparatus of claim 16, wherein the first component is associated with a first cold plate.

21. The apparatus of claim 20, wherein the liquid metal coolant is further used to cool a second component in the computer system, the second component associated with a second cold plate, wherein the pump is to enable the liquid metal coolant to flow in the tube from the first cold plate to the second cold plate in series.

22. The apparatus of claim 20, wherein the liquid metal coolant is further used to cool a third component in the computer system, the third component associated with a third cold plate, wherein the pump is to enable the liquid metal coolant to flow in the tube to the first cold plate and to the third cold plate in parallel.

23. The apparatus of claim 20, further comprising:
a heat spreader coupled to a fourth component to transfer heat generated by the fourth component, wherein the heat spreader is coupled to the first cold plate.

24. The apparatus of claim 16, further comprising:
a heat pipe coupled to a fifth component to transfer heat generated by the fifth component, wherein a condensation end of the heat pipe is cooled the heat exchanger.

25. The apparatus of claim 16, wherein the liquid metal includes a freezing point property of at least −10 degrees Celsius

26. A system, comprising:
a first electronic component;
a remote heat exchanger (RHE) coupled to the first electronic component; and
a pump coupled to the first electronic component and to the RHE, the pump is to enable a liquid metal coolant to flow toward and away from the RHE.

27. The system of claim 26, wherein the liquid metal coolant is to flow toward and away from the RHE in a tube.

28. The system of claim 26, wherein the liquid metal coolant includes a freezing property of at least −10 degrees Celsius.

29. The system of claim 26, further comprising:
a second electronic component coupled to the RHE, wherein the liquid metal coolant is to extract heat from the first electronic component and from the second electronic component in series.

30. The system of claim 26, further comprising:
a third electronic component coupled to the RHE, wherein the liquid metal coolant is to extract heat from the first electronic component and from the third electronic component in parallel.

31. The system of claim 26, further comprising:
a fourth electronic component coupled to a heat pipe to extract heat generated by the fourth electronic component, wherein vapor in the heat pipe is condensed into a working liquid by the RHE.

32. The system of claim 26, further comprising:
a fifth electronic component coupled to a heat spreader to extract heat generated by the fifth electronic component, wherein the heat spreader is further coupled to the first electronic component.

33. The system of claim 26, wherein the liquid metal coolant includes a mixture of Indium and Gallium.

34. The system of claim 33, wherein the liquid metal coolant further includes other metallic elements.

35. The system of claim 34, wherein the other metallic elements includes at least one of zinc and copper.

36. The system of claim 26, wherein the RHE is a single-pass RHE or a multi-pass RHE.

37. The system of claim 26, wherein the pump is an electromagnetic pump or a mechanical pump.

38. The system of claim 26, wherein the first electronic component is a processor or a graphics controller.

39. A method, comprising:
evacuating air from a loop used in a liquid cooling system to cool an electronic component in a system; and
filling the loop with a liquid metal coolant after the air is evacuated from the loop, wherein the liquid metal coolant is filled from a coolant container storing the liquid metal coolant at atmospheric pressure.

40. The method of claim 39, wherein a vacuum pump is used to evacuate the air from the loop.

41. The method of claim 40, wherein evacuating the air from the loop further comprises opening an air valve to enable the air to be evacuated from the loop by the vacuum pump, and closing the air valve after the air is sufficiently evacuated from the loop.

42. The method of claim 41, wherein the air is sufficiently evacuated from the loop when the air pressure in the loop is measured at less then 1 Torr.

43. The method of claim 41, wherein filling the loop comprises:
after the air is sufficiently evacuated from the loop, opening a coolant valve to fill the loop with the liquid metal coolant, and closing the coolant valve when the loop is completely filled with the liquid metal coolant.

44. The method of claim 39, wherein the loop includes one or more sections of tubes which are not heat pipes.
